(19) United States
(12) Patent Application Publication
(10) Pub. No.: US 2025/0196674 A1
(43) Pub. Date: Jun. 19, 2025

(54) CHARGING CABLE

(71) Applicant: TOYOTA JIDOSHA KABUSHIKI KAISHA, Toyota-shi (JP)

(72) Inventor: Masaru SASAKI, Toyota-shi (JP)

(73) Assignee: TOYOTA JIDOSHA KABUSHIKI KAISHA, Toyota-shi (JP)

(21) Appl. No.: 18/886,097

(22) Filed: Sep. 16, 2024

(30) Foreign Application Priority Data
Dec. 18, 2023 (JP) 2023-213266

(51) Int. Cl. B60L 53/18; G01R 31/54

(52) U.S. Cl. CPC B60L 53/18; G01R 31/54

(57) ABSTRACT

A charging cable includes a cable body including a plurality of power lines and a ground line, and a control box provided at an intermediate position of the cable body, the control box includes a detection device that detects disconnection of the ground line by monitoring grounding resistance of the ground line, and the detection device stores a plurality of reference resistance values corresponding to a plurality of grounding systems and detects the disconnection of the ground line by comparing the grounding resistance of the ground line with a reference resistance value corresponding to a designated grounding system.

### CROSS-REFERENCE TO RELATED APPLICATION

This application claims priority to Japanese Patent Application No. 2023-213266 filed on Dec. 18, 2023, incorporated herein by reference in its entirety.

### BACKGROUND

### 1. Technical Field

The technology disclosed herein relates to a charging cable for a vehicle.

### 2. Description of Related Art

Japanese Unexamined Patent Application Publication No. 2013-092466 (JP 2013-092466 A) discloses a ground fault detection device. The ground fault detection device performs ground fault determination of a high-voltage power supply system mounted on a vehicle based on a threshold value. The threshold value is switched in accordance with the state of the vehicle.

### SUMMARY

A grounding system that varies, for example, with countries or regions is adopted. Different grounding systems differ in grounding resistance. When the grounding resistance is different, a reference resistance value for use in detecting disconnection of the ground line is also different. The technology of JP 2013-092466 A is not considered for different grounding systems. The present specification provides a technique capable of correctly detecting the disconnection of the ground line with respect to a plurality of grounding systems.

The present specification discloses a charging cable for a vehicle. In a first aspect of the present technology, a charging cable includes a cable body including a plurality of power lines and a ground line; and a control box provided at an intermediate position of the cable body, the control box including a detection device that detects disconnection of the ground line by monitoring grounding resistance of the ground line, the detection device storing a plurality of reference resistance values corresponding to a plurality of grounding systems, and detecting the disconnection of the ground line by comparing the grounding resistance of the ground line with a reference resistance value corresponding to a designated grounding system.

In the above configuration, the detection device stores a plurality of reference resistance values corresponding to a plurality of grounding systems. Accordingly, when monitoring the grounding resistance of the ground line, the detection device can correctly detect the disconnection of the ground line by using a reference resistance value corresponding to a designated grounding system.

According to a second aspect, the first aspect further includes a user interface provided in the control box, and the user interface may be connected to the detection device and may be configured to accept designation of the grounding system by a user. According to the above configuration, the charging cable can accept the designation of the grounding system from the user. For this reason, it is possible to correctly detect the disconnection of the ground line with respect to the grounding system designated by the user.

According to a third aspect, in the second aspect, the user interface may include at least one of a plurality of buttons, a dial or a touch panel that is operated by the user. The user can designate a grounding system via at least one of the plurality of buttons, the dial, or the touch panel.

According to a fourth aspect, in any one of the above first to third aspects, the control box may further include a charging circuit interrupt device interposed on the power lines.

According to the fifth aspect, in any one of the first to fourth aspects, the grounding systems may include at least a TN grounding system, a TT grounding system, and an IT grounding system.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a schematic view of a charging cable;

FIG. 2 is a schematic diagram for explaining a TN grounding system;

FIG. 3 is a schematic diagram for explaining a TT grounding system; and

FIG. 4 is a schematic diagram for explaining an IT grounding system.

### DETAILED DESCRIPTION OF EMBODIMENTS

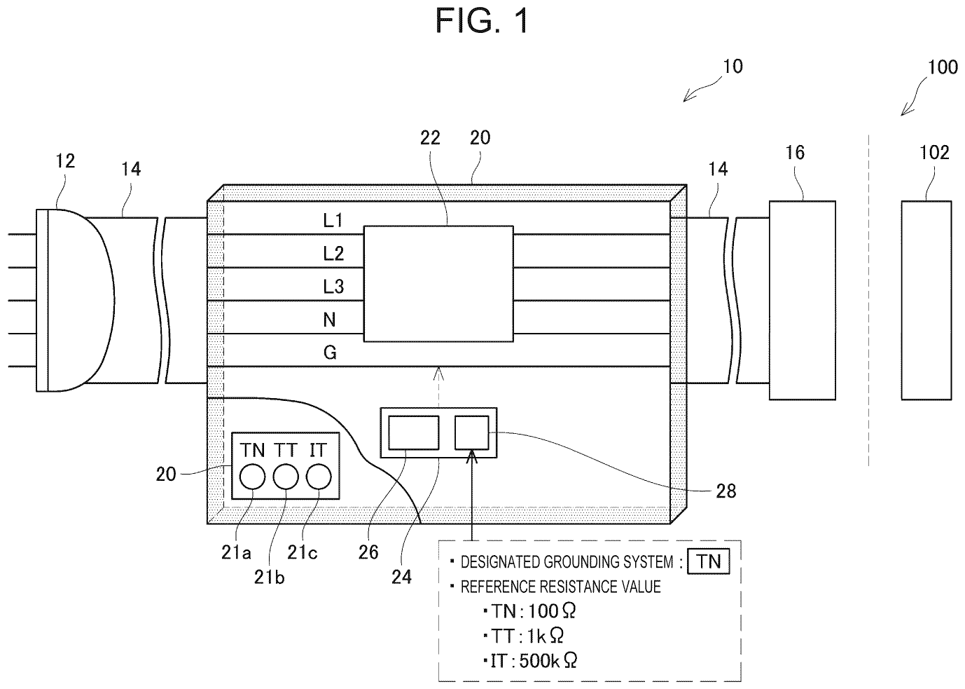

The charging cable 10 of the embodiment will be described with reference to the drawings. The charging cable 10 is used for charging electrified vehicle 100. As shown in FIG. 1, the charging cable 10 includes a plug 12, a cable body 14, a connector 16, and a control box 20. The plug 12 is provided at one end of the cable body 14 and is connected to an external power source. The connector 16 is provided at the other end of the cable body 14 and is connected to a charge inlet 102 of electrified vehicle 100. The charging cable 10 is usually mounted in a luggage compartment or the like of electrified vehicle 100 while being removed from the external power source and the charging inlet 102.

The cable body 14 includes a plurality of power lines L1, L2, L3, N and ground lines G. The control box 20 is provided at an intermediate position of the cable body 14. That is, the control box 20 is provided between the plug 12 and the connector 16 of the cable body 14. The charging cable 10 of the present embodiment is a so-called Mode 2 charging cable.

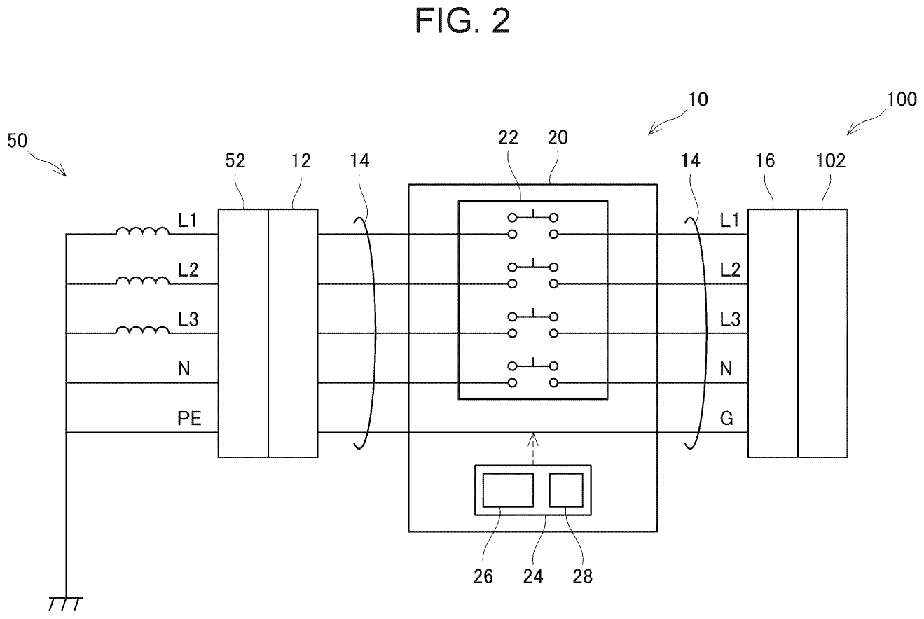

The control box 20 includes a charging circuit interrupt device (CCID) 22 and a detection device 24. The CCID 22 includes a relay (see FIG. 2 and the like) which is turned on/off by a control device (not shown). The detection device 24 detects a disconnection of the ground line G.

The detection device 24 stores a microcomputer 26 and a memory 28. The microcomputer 26 executes processing for detecting disconnection of the ground line G. Specifically, the microcomputer 26 detects disconnection of the ground line G by monitoring the grounding resistance of the ground line G.

Various grounding systems are known regarding the grounding of power supply systems and devices. For example, TN grounding system, TT grounding system, and IT grounding system are known. A grounding system that varies, for example, with countries or regions is adopted. In general, the reference of the resistance value of the ground line is different for each grounding system. When the reference of the resistance value of the ground line is different, the reference resistance value (that is, the threshold value) to be used for detecting the disconnection of the ground line is also different. When a common reference resistance value is used for a different grounding system, erroneous detection of a disconnection of a ground line (for example, a disconnection is detected even though a disconnection of a ground line does not actually occur, a disconnection is not detected in a situation where a disconnection of a ground line actually occurs, and the like) may occur.

Further, in order to correspond to the reference of the resistance value of the different ground lines, for example, a configuration of changing the components constituting the charging cable 10 such as the control box 20 used for each grounding system is conceivable. However, in this configuration, it is necessary to replace the components constituting the charging cable 10 such as the control box 20 according to the grounding system used. That is, the number of components constituting the charging cable 10 increases.

Therefore, in order to solve these problems, the memory 28 stores a plurality of reference resistance values corresponding to a plurality of grounding systems. The microcomputer 26 acquires the reference resistance value corresponding to the grounding system from the memory 28 in a state in which one of the plurality of grounding systems is designated. Then, the microcomputer 26 detects the disconnection of the ground line G by comparing the grounding resistance of the ground line G with the reference resistance value acquired from the memory 28 in a state in which one grounding system is designated. For this reason, the charging cable 10 of the present embodiment can be used uniformly in countries and regions in which any of the grounding systems of TN grounding system, TT grounding system, and IT grounding system is used without increasing the number of components constituting the charging cable 10 such as the control box 20.

As shown in FIG. 1, the control box 20 includes three buttons 21a to 21c. The buttons 21a to 21c are connected to the detection device 24. The button 21a is a button indicating a TN grounding system. A button 21b is a button indicating a TT grounding system. The button 21c is a button indicating an IT grounding system. When one of the buttons 21a to 21c is selected by the user, the grounding system corresponding to the selected button is stored in the memories 28 as the designated grounding system. In this way, the user can specify the grounding system by selecting one of the buttons 21a to 21c of the control box 20. The relationship between the various countries and regions and the grounding system employed therein is described in, for example, an instruction manual of the charging cable 10. The instruction manual may be a paper medium provided together with the charging cable 10 or may be displayed as a web page. In order to access the web page of the instruction manual, for example, a URL of the web page, a code image for accessing the web page, and the like may be described in the control box 20.

Hereinafter, each grounding system will be described with reference to FIGS. 2 to 4. First, referring to FIG. 2, a TN grounding system will be described. In TN grounding system, the power supply system is grounded at one place, and a protective grounding conductor PE for grounding the device at that point is provided. TN grounding system illustrated in FIG. 2 is a so-called TN-S grounding system that separates the neutral line N and the protective grounding conductor PE. As TN grounding system, in addition to TN-S grounding system, a grounding system in which the neutral line N and the protective grounding conductor PE are shared, a TN-C grounding system in which the neutral line N and the protective grounding conductor PE are partially shared, and a TN-C-N grounding system are known. TN grounding system is, for example, a grounding system widely adopted in Europe and the United States.

As shown in FIG. 2, the plug 12 of the charging cable 10 is connected to the outlet 52 of the power supply system 50. The connector 16 of the charging cable 10 is connected to a charging inlet 102 of electrified vehicle 100. If a TN grounding system is employed, the equipment (e.g., outlet 52) is connected to the ground of the power supply system 50 via a protective grounding conductor PE. Further, the ground line G of the cable body 14 is connected to the protective grounding conductor PE. Therefore, in a situation where grounding is correctly performed, the grounding resistance of the ground line G becomes a value relatively close to zero.

Therefore, the reference resistance value corresponding to TN grounding system stored in the memory 28 is set to a relatively small value (for example, 100 (2). When using the charging cable 10 in an area where TN grounding system is adopted, the user selects the button 21a of the control box 20. Then, the detection device 24 acquires the reference resistance value corresponding to TN grounding system from the memories 28. Then, the detection device 24 monitors the grounding resistance of the ground line G, and detects the disconnection of the ground line G based on the grounding resistance of the ground line G and the acquired reference resistance value. For example, when the grounding resistance of the ground line G is larger than the reference resistance value, the disconnection of the ground line G may be detected. In this way, when TN grounding system is adopted, the disconnection of the ground line G can be detected by using the corresponding reference resistance value. That is, the disconnection of the ground line G can be correctly detected.

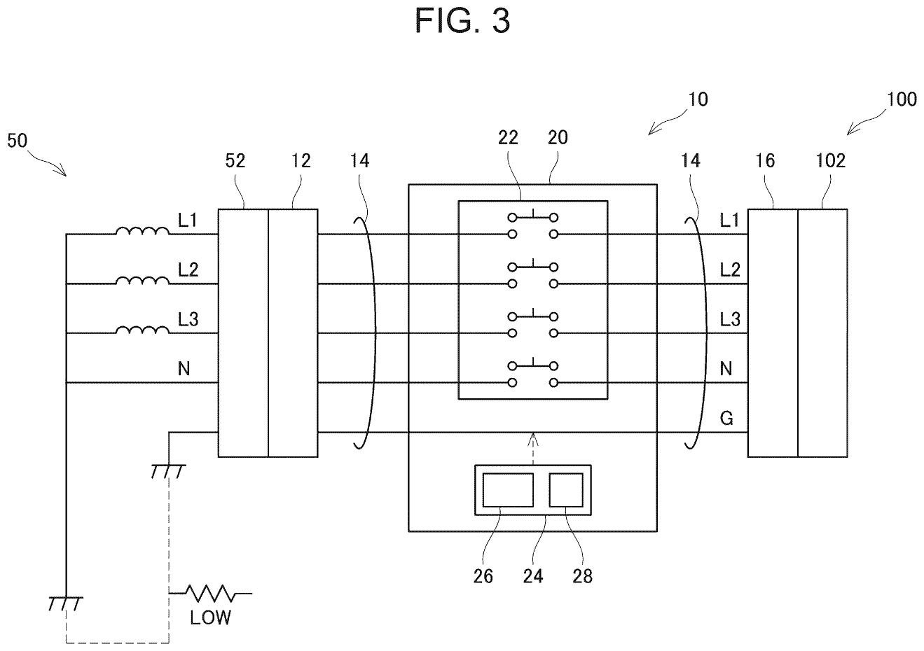

Next, referring to FIG. 3, a TT grounding system will be described. In TT grounding system, the power supply system is grounded at one place, but the protective grounding conductors are not supplied, and the grounding of the power supply system and the grounding of the equipment are performed independently. TT grounding system is, for example, a grounding system widely adopted in Japan.

As shown in FIG. 3, when a TT grounding system is employed, the device (e.g., outlet 52) is grounded independently of the grounding of the power supply system 50. The ground line G of the cable body 14 is connected to the ground of the device via the outlet 52. A relatively small impedance is generated between the ground of the power supply system 50 and the ground of the device. Therefore, in a situation where grounding is correctly performed, the grounding resistance of the ground line G becomes a relatively small value. That is, in a situation where the grounding is correctly performed, the grounding resistance of the ground line G in TT grounding system is larger than the grounding resistance of the ground line G in TN grounding system.

Therefore, the reference resistance value corresponding to TT grounding system stored in the memories 28 is set to a value (for example, 1 kΩ) larger than the reference resistance value corresponding to TN grounding system. When using the charging cable 10 in an area where TT grounding system is adopted, the user selects the button 21b of the control box 20. Then, the detection device 24 acquires the reference resistance value corresponding to TT grounding system from the memories 28. Then, the detection device 24 monitors the grounding resistance of the ground line G, and detects the disconnection of the ground line G based on the grounding resistance of the ground line G and the acquired reference resistance value. In this way, when TT grounding system is adopted, the disconnection of the ground line G can be detected by using the corresponding reference resistance value. That is, the disconnection of the ground line G can be correctly detected.

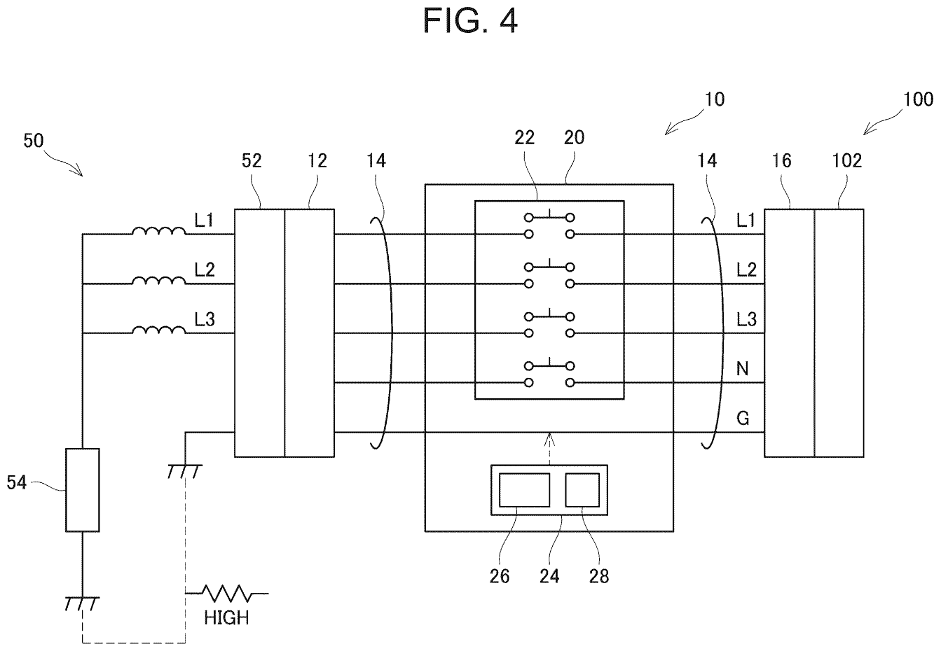

Next, referring to FIG. 4, an IT grounding system will be described. In IT grounding system, the power supply system is not grounded at all or is grounded via high-impedance. In the example of FIG. 4, the power supply system 50 is grounded via the high impedance 54. IT grounding system is, for example, a grounding system widely adopted in Norway and the like.

As shown in FIG. 4, when IT grounding system is employed, the device (e.g., outlet 52) is grounded independently of the grounding of the power supply system 50. The ground line G of the cable body 14 is connected to the ground of the device via the outlet 52. Since the power supply system 50 is grounded via the high impedance 54, a relatively large impedance is generated between the grounding of the power supply system 50 and the grounding of the device. Therefore, in a situation where grounding is correctly performed, the grounding resistance of the ground line G becomes a relatively large value. That is, in a situation where the grounding is correctly performed, the grounding resistance of the ground line G in IT grounding system is larger than the grounding resistance of the ground line G in TN grounding system and the grounding resistance of the ground line G in TT system.

Therefore, the reference resistance value corresponding to IT grounding system stored in the memory 28 is set to a value (for example, 500 kΩ) larger than the reference resistance value corresponding to TN grounding system and the reference resistance value corresponding to TT grounding system. When using the charging cable 10 in an area where IT grounding system is adopted, the user selects the button 21c of the control box 20. Then, the detection device 24 acquires the reference resistance value corresponding to IT grounding system from the memories 28. Then, the detection device 24 monitors the grounding resistance of the ground line G, and detects the disconnection of the ground line G based on the grounding resistance of the ground line G and the acquired reference resistance value. In this way, when IT grounding system is adopted, the disconnection of the ground line G can be detected by using the corresponding reference resistance value. That is, the disconnection of the ground line G can be correctly detected.

In IT grounding system, the grounding resistance of the ground line G is relatively large when the grounding is correctly performed by the grounding system. Accordingly, the reference resistance value corresponding to IT grounding system is also set to a relatively large value. It is not normally assumed that a grounding resistance exceeding this reference resistance value is detected. Therefore, in IT grounding system, it can be said that disconnection detection of the ground line G is substantially unnecessary.

As described above, in the configuration of the present embodiment, the memory 28 of the detection device 24 stores a plurality of reference resistance values corresponding to a plurality of grounding systems. Accordingly, when monitoring the grounding resistance of the ground line G, the detection device 24 can correctly detect the disconnection of the ground line G by using the reference resistance value corresponding to the designated grounding system. In particular, the charging cable 10 of the present embodiment can be used uniformly in countries and regions where any of the grounding systems of TN grounding system, TT grounding system, and IT grounding system is used without increasing the number of components constituting the charging cable 10 such as the control box 20.

The buttons 21a to 21c are examples of the “user interface” of the present technique.

Although the specific examples disclosed by the present disclosure have been described in detail above, these are merely examples and do not limit the scope of claims. The techniques described in the claims include various modifications and alternations of the specific example illustrated above. Modifications of the above-described embodiment are listed below.

### First Modification

The control box 20 may not include the buttons 21a to 21c. In this case, the grounding system may be designated by another method (for example, communication). In the present modification, the “user interface” can be omitted.

### Second Modification

The control box 20 may include, in addition to or instead of buttons 21a to 21c, a dialing for designating a grounding system, a touch panel capable of designating a grounding system, and the like. In the present modification, a dial, a touch panel, or the like is an example of a “user interface” of the present technology. Generally speaking, the “user interface” of the present technology may be any type as long as it is configured to accept designation of a grounding system by a user.

### Third Modification

In the above embodiments, TN grounding system, TT grounding system, and IT grounding system have been described, but the present technique is also useful for a grounding system that differs from these grounding systems.

The technical elements described in the present specification or drawings exhibit technical usefulness alone or in various combinations, and are not limited to the combinations described in the claims at the time of filing. In addition, the techniques illustrated in the present specification or drawings can achieve a plurality of objectives at the same time, and achieving one of the objectives itself has technical usefulness.

What is claimed is:

1. A charging cable for a vehicle comprising:
a cable body including a plurality of power lines and a ground line; and
a control box provided at an intermediate position of the cable body, the control box including a detection device that detects disconnection of the ground line by monitoring grounding resistance of the ground line, the detection device storing a plurality of reference resistance values corresponding to a plurality of grounding systems, and detecting the disconnection of the ground line by comparing the grounding resistance of the ground line with a reference resistance value corresponding to a designated grounding system.

2. The charging cable according to claim 1, further comprising a user interface provided in the control box, the user interface being connected to the detection device and being configured to accept designation of a grounding system by a user.

3. The charging cable according to claim 2, wherein the user interface includes at least one of a plurality of buttons, a dial or a touch panel that is operated by the user.

4. The charging cable according to claim 1, wherein the control box further includes a charging circuit interrupt device interposed on the power lines.

5. The charging cable according to claim 1, wherein the grounding systems includes at least a TN grounding system, a TT grounding system, and an IT grounding system.
